(19) United States
(12) Patent Application Publication
(10) Pub. No.: US 2026/0173936 A1
(43) Pub. Date: Jun. 18, 2026

(54) CERAMIC SUBSTRATE, SEMICONDUCTOR DEVICE PACKAGE, ELECTROSTATIC CHUCK, AND SUBSTRATE FIXING DEVICE

(71) Applicant: SHINKO ELECTRIC INDUSTRIES CO., LTD., Nagano-shi (JP)

(72) Inventors: Tomotake Minemura, Nagano (JP); Yuichiro Shimizu, Nagano (JP); Koji Nagai, Nagano (JP); Michio Horiuchi, Nagano (JP)

(21) Appl. No.: 19/412,255

(22) Filed: Dec. 8, 2025

(30) Foreign Application Priority Data
Dec. 12, 2024 (JP) 2024-217544

(51) Int. Cl. H01L 23/15; H01L 21/683

(52) U.S. Cl. CPC H10W 70/692; H10P 72/722

(57) ABSTRACT

A ceramic substrate includes a base body made of ceramic to which an inorganic component other than aluminum oxide is not added, and a conductor layer in contact with the base body. The conductor layer includes a first layer that is a sintered body mainly composed of metal and including aluminum oxide, a second layer that is a sintered body stacked on the first layer, mainly composed of metal, and not including aluminum oxide, and a third layer that is a sintered body stacked on the second layer, mainly composed of metal, and including aluminum oxide.

### CROSS-REFERENCE TO RELATED APPLICATIONS

This application claims priority from Japanese Patent Application No. 2024-217544 filed on Dec. 12, 2024, the contents of which are incorporated herein by reference.

### TECHNICAL FIELD

The present invention relates to a ceramic substrate, a semiconductor device package, an electrostatic chuck, and a substrate fixing device.

### BACKGROUND ART

In the related art, a film formation apparatus and a plasma etching apparatus, which are used when manufacturing a semiconductor device, each have a stage for accurately holding a wafer in a vacuum treatment chamber. As such a stage, for example, a substrate fixing device is suggested which adsorbs and holds a wafer by an electrostatic chuck mounted on a base plate.

The electrostatic chuck includes a ceramic substrate having a base body that is an insulator layer and a conductor layer embedded in the base body. The conductor layer is obtained by forming a conductive paste including, for example, tungsten and molybdenum on a ceramic green sheet by a screen printing method or the like, and firing it (see, for example, Patent Literature 1).

### CITATION LIST

### Patent Literature

PTL 1: JPH07-321431A

### SUMMARY OF INVENTION

When the base body is formed of aluminum oxide ceramic, adhesion between the base body and the conductor layer may not be achieved because the ceramic does not contain a sintering aid. Although the adhesion is improved by adding aluminum oxide to the conductor layer, it may be undesirable because the resistivity of the entire conductor layer increases.

An object of the present disclosure is to achieve, in a ceramic substrate having a base body made of aluminum oxide ceramic and a conductor layer in contact with the base body, both improved adhesion between the base body and the conductor layer and reduced resistivity of the conductor layer.

A ceramic substrate includes a base body made of ceramic to which an inorganic component other than aluminum oxide is not added, and a conductor layer in contact with the base body. The conductor layer includes a first layer that is a sintered body mainly composed of metal and including aluminum oxide, a second layer that is a sintered body stacked on the first layer, mainly composed of metal, and not including aluminum oxide, and a third layer that is a sintered body stacked on the second layer, mainly composed of metal, and including aluminum oxide.

According to the disclosed technology, in a ceramic substrate including a base body made of aluminum oxide ceramic and a conductor layer embedded in the base body, both improved adhesion between the base body and the conductor layer and reduced resistivity of the conductor layer can be achieved.

### BRIEF DESCRIPTION OF DRAWINGS

FIGS. 1A and 1B are cross-sectional views illustrating a simplified example of a substrate fixing device according to a first embodiment.

FIGS. 2A to 2D are views illustrating an example of a part of a manufacturing process of an electrostatic chuck according to a first embodiment.

FIGS. 3A and 3B are images of cross-sectional SEM photographs of an RF electrode manufactured using the method shown in FIGS. 2A to 2D.

FIG. 4 is a cross-sectional view illustrating an example of a semiconductor device package according to a second embodiment.

FIG. 5 is a plan view illustrating the example of the semiconductor device package according to the second embodiment.

### DESCRIPTION OF EMBODIMENTS

Hereinafter, embodiments of the present invention will be described with reference to the drawings. Note that, in the respective drawings, the parts having the same configurations are denoted with the same reference signs, and the redundant descriptions may be omitted.

### First Embodiment

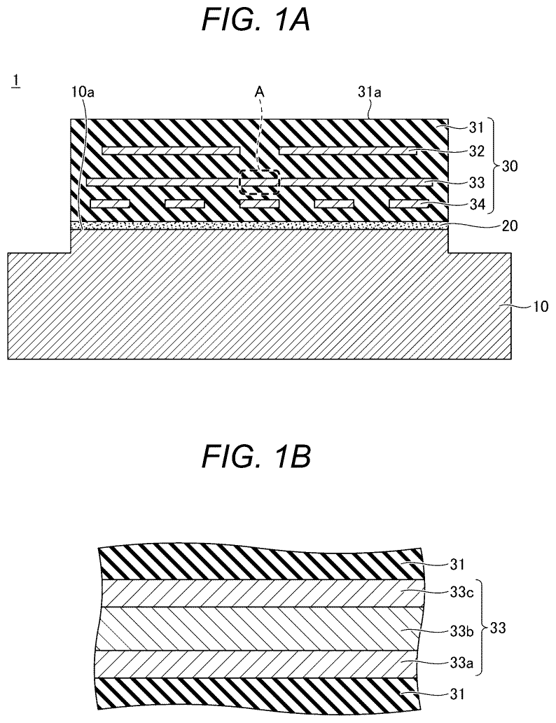

FIGS. 1A and 1B are cross-sectional views illustrating a simplified example of a substrate fixing device according to a first embodiment, in which FIG. 1A is an overall view, and FIG. 1B is an enlarged view of part A of FIG. 1A.

Referring to FIG. 1A, a substrate fixing device 1 has, as main constitutional elements, a base plate 10, an adhesive layer 20, and an electrostatic chuck 30. The substrate fixing device 1 is a device that adsorbs and holds a substrate (a wafer or the like), which is a target object to be adsorbed, by the electrostatic chuck 30 mounted on one surface of the base plate 10.

The base plate 10 is a member for mounting the electrostatic chuck 30. A thickness of the base plate 10 is, for example, about 20 to 50 mm. The base plate 10 may be formed of, for example, metal such as aluminum, copper, or titanium. Among them, aluminum is preferably used which is inexpensive and easy to process.

A water channel may be provided inside the base plate 10. In this case, the water channel is connected to a cooling water control device provided outside the substrate fixing device 1, and the cooling water control device introduces and discharges cooling water into and from the water channel. By circulating cooling water through the water channel using the cooling water control device to cool the base plate 10, the wafer adsorbed on the electrostatic chuck 30 can be cooled. In addition to the water channel, a gas channel for introducing an inert gas to cool the wafer adsorbed on the electrostatic chuck 30, or the like may be provided in the base plate 10.

The electrostatic chuck 30 is mounted on one surface 10a of the base plate 10 via the adhesive layer 20. As the adhesive layer 20, silicone-based resin may be used, for example.

A thickness of the adhesive layer 20 is, for example, about 0.1 to 1.0 mm. The adhesive layer 20 bonds the base plate 10 and the electrostatic chuck 30, and has an effect of reducing stress generated due to a difference in thermal expansion coefficient between the electrostatic chuck 30 made of ceramic and the base plate 10 made of aluminum.

A thermal conductivity of the adhesive layer 20 is preferably set to 2 W/mK or higher. The adhesive layer 20 may be formed as a single layer, but preferably has a two-layer structure combining an adhesive with high thermal conductivity and an adhesive with low elasticity. This can reduce the stress resulting from the difference in thermal expansion rates between the electrostatic chuck 30 made of ceramic and the base plate 10 made of aluminum and can improve heat dissipation.

The electrostatic chuck 30 is a part that adsorbs and holds the substrate, which is a target object to be adsorbed. A planar shape of the electrostatic chuck 30 may be circular, for example. A diameter of the substrate, which is a target object to be adsorbed of the electrostatic chuck 30, may be, for example, 6 inches, 8 inches, 12 inches, or 18 inches. The electrostatic chuck 30 is, for example, a Johnsen-Rahbek type electrostatic chuck. However, the electrostatic chuck 30 may also be a Coulomb-type electrostatic chuck.

A base body 31 is a dielectric body. Specifically, the base body 31 is ceramic made of aluminum oxide (Al₂O₃). Here, “ceramic made of aluminum oxide” refers to ceramic to which an inorganic component other than aluminum oxide is not added. A thickness of the base body 31 is, for example, about 5 to 10 mm, and a relative permittivity (1 kHz) of the base body 31 is, for example, about 9 to 10.

The base body 31 preferably has a purity of aluminum oxide of 99.5% or higher. The purity of 99.5% or higher indicates that a sintering aid is not added. In addition, the purity of 99.5% or higher means that unintended impurities may be included during a manufacturing process and the like. The base body 31 preferably has a relative density of 97% or more with respect to aluminum oxide. The base body 31 preferably has an average particle diameter of aluminum oxide of 1.0 μm or more and 3.0 μm or less.

The electrostatic chuck 30 has the base body 31 and one or more conductor layers in contact with the base body 31. The electrostatic chuck 30 is one example of the claimed ceramic substrate. In the example of FIG. 1, the conductor layer includes an electrostatic electrode 32, an RF electrode 33, and a heating element 34 embedded in the base body 31. The conductor layer may include a layer other than these layers.

The electrostatic electrode 32 is a thin film electrode. The electrostatic electrode 32 is connected to a power supply provided outside the substrate fixing device 1, and generates adsorption force between the electrostatic electrode and the substrate by static electricity when a predetermined voltage is applied from the power supply. This enables the substrate to be adsorbed and held on a placement surface 31a of the base body 31 of the electrostatic chuck 30. The higher the voltage applied to the electrostatic electrode 32, the stronger the adsorption holding force. The electrostatic electrode 32 may have a unipolar shape or a bipolar shape. The electrostatic electrode 32 is a sintered body mainly composed of metal. The electrostatic electrode 32 may be a sintered body mainly composed of metal and including aluminum oxide. Examples of metal include tungsten and molybdenum.

The RF electrode 33 may be arranged, for example, in a region excluding an outer peripheral portion of the base body 31. The RF electrode 33 is provided to increase the anisotropy of plasma etching and improve the efficiency of etching when the substrate fixing device 1 is used for plasma etching, and high-frequency power for plasma control is supplied. The supply of high-frequency power by the RF electrode 33 is used to efficiently attract plasma, for example, when forming a hole having a high aspect ratio with plasma.

The RF electrode 33 is preferably arranged in a substantially solid shape in order to uniformly attract plasma.

The heating element 34 generates heat by applying a voltage from a control circuit provided outside the substrate fixing device 1, and heats the placement surface 31a of the electrostatic chuck 30 to a predetermined temperature. The heating element 34 can heat, for example, the placement surface 31a of the electrostatic chuck element 30 to the temperature of about 60° C. to 300° C. The heating element 34 is a sintered body mainly composed of metal. The heating element 34 may be a sintered body mainly composed of metal and including aluminum oxide. Examples of metal include tungsten and molybdenum.

As shown in FIG. 1B, the RF electrode 33, which is a conductor layer, includes a first layer 33a, a second layer 33b, and a third layer 33c. The second layer 33b is stacked on the first layer 33a. The second layer 33b is in close contact with the first layer 33a. The third layer 33c is stacked on the second layer 33b. The third layer 33c is in close contact with the second layer 33b. The first layer 33a is a sintered body mainly composed of metal and including aluminum oxide. The second layer 33b is a sintered body mainly composed of metal and not including aluminum oxide. The third layer 33c is a sintered body mainly composed of metal and including aluminum oxide.

Examples of metals that are the main components of the first layer 33a, the second layer 33b, and the third layer 33c include materials such as tungsten, molybdenum, copper, aluminum, nickel, gold, silver, titanium, cobalt, rhenium, tantalum, manganese, palladium, and platinum, and alloys thereof. Among these, tungsten or molybdenum is preferably used in terms of melting point or cost. The first layer 33a, the second layer 33b, and the third layer 33c may be mainly composed of the same metal, or may be mainly composed of different metals. For example, the first layer 33a and the third layer 33c may be mainly composed of tungsten, and the second layer 33b may be mainly composed of molybdenum.

A thickness of each of the first layer 33a, the second layer 33b, and the third layer 33c may be, for example, 5 μm or more and 100 μm or less. The thickness of each of the first layer 33a, the second layer 33b, and the third layer 33c may be set independently. Two or more of the first layer 33a, the second layer 33b, and the third layer 33c may have the same thickness. Note that the electrostatic electrode 32 and/or the heating element 34 may have a stacked structure similar to that of the RF electrode 33.

As such, in the present embodiment, at least one conductor layer embedded in the base body made of aluminum oxide ceramic is configured as a plurality of layers, and layers each made of a sintered body including aluminum oxide are arranged as the upper and lower layers. This can improve adhesion between the aluminum oxide ceramic and the stacked body of the conductor layer. On the other hand, in the conductor layer, as the proportion of aluminum oxide, which is an insulator, increases, the resistivity decreases, but a layer made of a sintered body not including aluminum oxide is included in the conductor layer, so that the resistivity of the entire conductor layer can be reduced.

That is, according to the present embodiment, in the ceramic substrate including the base body made of aluminum oxide ceramic and the conductor layer in contact with the base body, both improved adhesion between the base body and the conductor layer and reduced resistivity of the conductor layer can be achieved. This structure is suitable for use in an electrode requiring low resistance, such as the RF electrode 33 embedded in the base body 31. Note that the resistivity of the entire conductor layer can be controlled by changing the ratio of the thickness of each layer.

### Method for Manufacturing Electrostatic Chuck

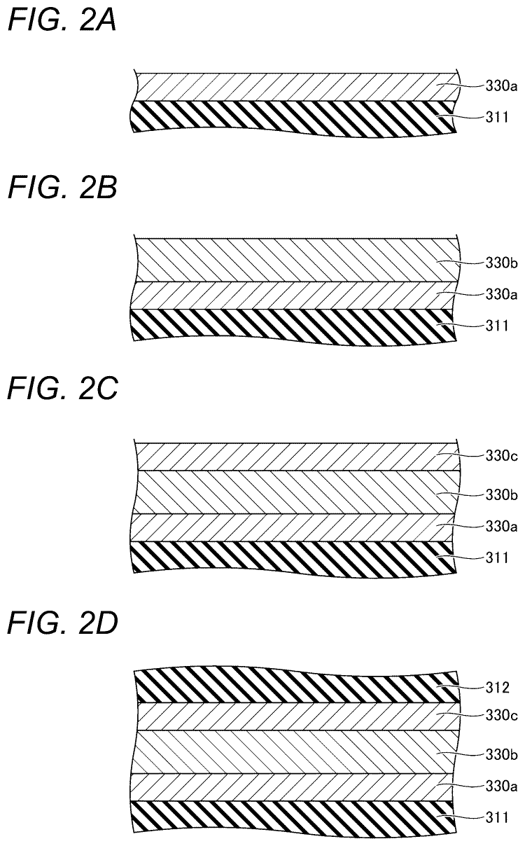

FIGS. 2A to 2D are views illustrating an example of a part of a manufacturing process of an electrostatic chuck according to a first embodiment. In FIGS. 2A to 2D, a method for manufacturing the electrostatic chuck 30 is described, mainly with respect to a method for manufacturing the RF electrode 33.

To manufacture the RF electrode 33, first, as shown in FIG. 2A, a green sheet 311 made of a ceramic material and an organic material is prepared. The green sheet 311 is formed, for example, in the shape of a rectangular plate. The ceramic material of the green sheet 311 is aluminum oxide, and includes a binder, a plasticizer, and a dispersant, but does not include a sintering aid. That is, the green sheet 311 has a high purity of aluminum oxide. The green sheet 311 becomes a part of the base body 31 shown in FIG. 1B by removing organic components, and sintering and densifying the ceramic material.

Next, a first conductor pattern 330a is formed by printing a conductive paste on an upper surface of the green sheet 311, for example, by a printing method (screen printing). The first conductor pattern 330a becomes the first layer 33a of the RF electrode 33 shown in FIG. 1B by being fired in a process described below.

The conductive paste used to form the first conductor pattern 330a is, for example, a paste mainly composed of tungsten, with aluminum oxide added and an organic material further mixed therein. An amount of aluminum oxide added is preferably 3.0 wt % or more with respect to tungsten. Aluminum oxide is preferably added in an amount of 3.0 wt % or more in order to improve the adhesion of the RF electrode 33 to the base body 31 made of aluminum oxide ceramic. In co-firing the conductive paste and the green sheet, the average particle diameter of the aluminum oxide is preferably 0.1 μm or more and 10.0 μm or less.

Next, as shown in FIG. 2B, a second conductor pattern 330b is formed by printing a conductive paste on an upper surface of the first conductor pattern 330a by, for example, a printing method (screen printing). The second conductor pattern 330b becomes the second layer 33b of the RF electrode 33 shown in FIG. 1B by being fired in a process described below.

The conductive paste used to form the second conductor pattern 330b is, for example, a paste mainly composed of tungsten, with an organic material mixed therein. The conductive paste used to form the second conductor pattern 330b does not include aluminum oxide.

Next, as shown in FIG. 2C, a third conductor pattern 330c is formed by printing a conductive paste on an upper surface of the second conductor pattern 330b by, for example, a printing method (screen printing). The third conductor pattern 330c becomes the third layer 33c of the RF electrode 33 shown in FIG. 1B by being fired in a process described below.

The conductive paste used to form the third conductor pattern 330c is, for example, a paste mainly composed of tungsten, with aluminum oxide added and an organic material further mixed therein. A thickness of the third conductor pattern 330c may be the same as or different from a thickness of the first conductor pattern 330a. In the conductive paste used to form the third conductor pattern 330c, the amount of aluminum oxide added and the average particle diameter of aluminum oxide may be, for example, similar to those of the conductive paste used to form the first conductor pattern 330a.

Next, as shown in FIG. 2D, a green sheet 312 made of a material similar to that of the green sheet 311 and having a similar shape is prepared. Then, the green sheet 312 is placed on the green sheet 311 to cover the stack of the first conductor pattern 330a, the second conductor pattern 330b, and the third conductor pattern 330c. The green sheet 312 becomes a part of the base body 31 shown in FIG. 1B by removing organic components, and sintering and densifying the ceramic material.

Next, by firing the structure shown in FIG. 2D, the RF electrode 33 embedded in the base body 31 is formed, as shown in FIG. 1B. The firing may be carried out, for example, at atmospheric pressure. The temperature during firing may be set to, for example, 1600° C. The aluminum oxide included in the first conductor pattern 330a and the third conductor pattern 330c functions as a co-material of the base body 31, thereby improving adhesion to the base body 31.

Note that, in the conductive pastes used to form the first conductor pattern 330a, the second conductor pattern 330b, and the third conductor pattern 330c, molybdenum may be used instead of tungsten. In this case, the presence or absence of addition of aluminum oxide is the same as in the case of tungsten.

Although the method of manufacturing the RF electrode is described here, the electrostatic electrode 32 and the heating element 34 can also be manufactured by the same method. For example, a plurality of green sheets are prepared, and the green sheets and conductive pastes are sequentially stacked so that the electrostatic electrode 32, the RF electrode 33, and the heating element 34 are arranged as shown in FIG. 1A, followed by collective co-firing. As a result, the base body 31 in which the electrostatic electrode 32, the RF electrode 33, and the heating body 34 are embedded can be manufactured.

Thereafter, various processing is performed on the base body 31 to complete the electrostatic chuck 30. For example, the upper and lower surfaces of the base body 31 are polished to form the placement surface 31a and the adhesive surface. Additionally, opening portions for lift pins, etc. are formed in the base body 31 as needed.

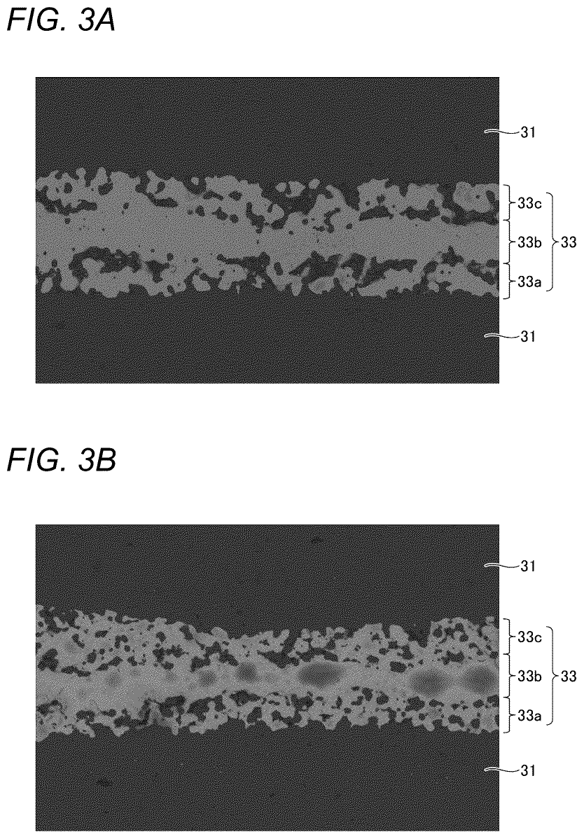

FIGS. 3A and 3B are images of cross-sectional SEM photographs of an RF electrode manufactured using the method shown in FIGS. 2A to 2D. The magnification of the photograph is 1000×. FIG. 3A shows a case in which the first conductor pattern 330a, the second conductor pattern 330b, and the third conductor pattern 330c are formed by sintering using a conductive paste mainly composed of tungsten. The thickness of each of the first layer 33a, the second layer 33b, and the third layer 33c is 10μm.

As shown in FIG. 3A, no peeling or the like is observed at the joining portions of the respective layers. In addition, the resistivity of the RF electrode 33 shown in FIG. 3A was 1.5×10⁻⁵ Ω·cm. On the other hand, it has been found that the resistivity is 2.5×10⁻⁵ Ω·cm when the RF electrode 33 is formed only of the first layer 33a mainly composed of tungsten with aluminum oxide added and the third layer 33c mainly composed of tungsten with aluminum oxide added. That is, the RF electrode 33, by including the second layer 33b mainly composed of tungsten without aluminum oxide added, has reduced resistivity compared with the case in which it is formed only of conductor layers mainly composed of tungsten with aluminum oxide added.

FIG. 3B shows a case in which the first conductor pattern 330a, the second conductor pattern 330b, and the third conductor pattern 330c are formed by sintering using a conductive paste mainly composed of molybdenum. The thickness of each of the first layer 33a, the second layer 33b, and the third layer 33c is 10 μm.

As shown in FIG. 3B, no peeling or the like is observed at the joining portions of the respective layers. In addition, the resistivity of the RF electrode 33 shown in FIG. 3b was 1.5×10⁻⁵ Ω·cm. On the other hand, it has been found that the resistivity is 3.2×10⁻⁵ Ω·cm when the RF electrode 33 is formed only of the first layer 33a mainly composed of molybdenum with aluminum oxide added and the third layer 33c mainly composed of molybdenum with aluminum oxide added. That is, the RF electrode 33, by including the second layer 33b mainly composed of molybdenum without aluminum oxide added, has reduced resistivity compared with the case in which it is formed only of conductor layers mainly composed of molybdenum with aluminum oxide added.

### Second Embodiment

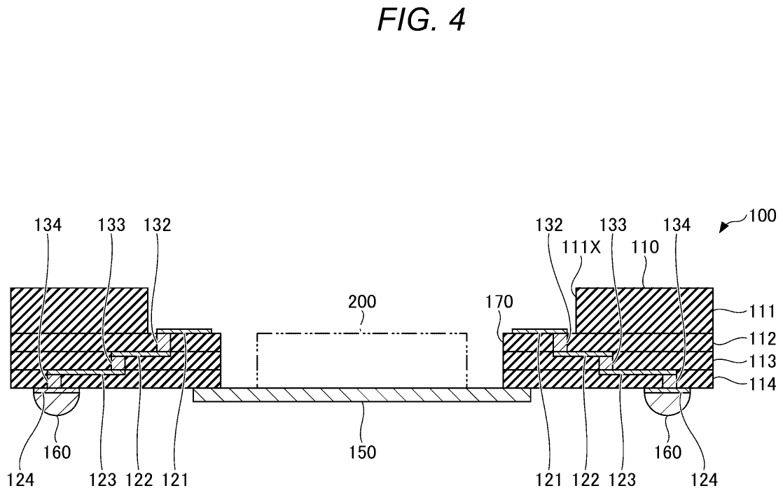

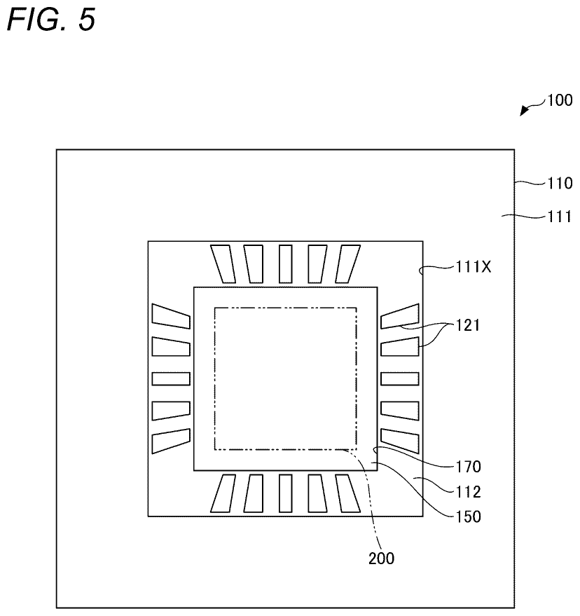

In a second embodiment, an example of a semiconductor device package having a ceramic substrate including a conductor layer described in the first embodiment is shown. FIG. 4 is a cross-sectional view illustrating an example of a semiconductor device package according to a second embodiment. FIG. 5 is a plan view illustrating the example of the semiconductor device package according to the second embodiment.

As shown in FIG. 4, a semiconductor device package 100 includes a ceramic substrate 110, a heat-dissipating plate 150, and an external connection terminal 160, and the heat-dissipating plate 150 is soldered to the ceramic substrate 110.

The ceramic substrate 110 includes a plurality of (four in this embodiment) stacked ceramic base materials 111, 112, 113, and 114, wiring patterns 121, 122, 123, and 124, and vias 132, 133, and 134 penetrating the ceramic base materials 112, 113, and 114. The via 132 connects the wiring patterns 121 and 122 to each other, the via 133 connects the wiring patterns 122 and 123 to each other, and the via 134 connects the wiring patterns 123 and 124 to each other. In the ceramic substrate 110, the ceramic base materials 111 to 114 constitute a base body.

As shown in FIGS. 4 and 5, the ceramic substrate 110 has a cavity 170 penetrating central portions of the ceramic base materials 112, 113 and 114 and provided to mount a semiconductor element 200 therein. The wiring pattern 121 is arranged on an upper surface of the ceramic base material 112 so as to surround the cavity 170. An opening portion 111X that exposes the wiring pattern 121 is formed in the ceramic base material 111.

Each of the ceramic base materials 111 to 114 is ceramic mad of aluminum oxide. Each of the ceramic base materials 111 to 114 is one example of the claimed base body.

In addition, the wiring patterns 121 to 124 are conductor layers having a stacked structure shown in FIG. 1B. That is, the wiring patterns 121 to 124 include a first layer, a second layer stacked on the first layer, and a third layer stacked on the second layer. In the wiring patterns 121 to 124, each of the first layer and the third layer is a sintered body mainly composed of, for example, tungsten or molybdenum and including aluminum oxide. The second layer is a sintered body mainly composed of, for example, tungsten or molybdenum and not including aluminum oxide. In addition, each of the vias 132 to 134 is, for example, a sintered body mainly composed of molybdenum and including nickel oxide, aluminum oxide, and silicon dioxide.

The ceramic substrate 110 may be manufactured by the same manufacturing method as the electrostatic chuck 30 of the first embodiment.

In the semiconductor device package 100, the semiconductor element 200 is mounted on the heat-dissipating plate 150. A pad of the semiconductor element 200 is electrically connected to the wiring pattern 121 of the ceramic substrate 110 by a bonding wire or the like. In this way, the semiconductor element 200 is connected to the external connection terminal 160 via the wiring patterns 121 to 124 and the vias 132 to 134.

In the semiconductor device package 100, as in the first embodiment, the adhesion between the ceramic base materials 111 to 114 each made of aluminum oxide and the wiring patterns 121 to 124 in contact with the ceramic base materials 111 to 114 can be improved. Additionally, the resistivity of the wiring patterns 121 to 124 can be reduced.

Although the preferred embodiments and the like have been described in detail, the present invention is not limited to the above-described embodiments and the like, and a variety of changes and replacements can be made for the above-described embodiments and the like without departing from the scope defined in the claims.

What is claimed is:

1. A ceramic substrate comprising:
a base body made of ceramic to which an inorganic component other than aluminum oxide is not added; and
a conductor layer in contact with the base body,
wherein the conductor layer comprises
a first layer that is a sintered body mainly composed of metal and including aluminum oxide,
a second layer that is a sintered body stacked on the first layer, mainly composed of metal, and not including aluminum oxide, and
a third layer that is a sintered body stacked on the second layer, mainly composed of metal, and including aluminum oxide.

2. The ceramic substrate according to claim 1, wherein the metal is tungsten or molybdenum.

3. The ceramic substrate according to claim 1, wherein the base body has a purity of the aluminum oxide of 99.5% or more.

4. The ceramic substrate according to claim 3, wherein the base body has a relative density of 97% or more with respect to the aluminum oxide.

5. The ceramic substrate according to claim 3, wherein the base body has an average particle diameter of the aluminum oxide of 1.0 μm or more and 3.0 μm or less.

6. A semiconductor device package comprising the ceramic substrate according to claim 1.

7. An electrostatic chuck comprising:
a base body made of ceramic to which an inorganic component other than aluminum oxide is not added; and
an RF electrode in contact with the base body,
wherein the RF electrode comprises
a first layer that is a sintered body mainly composed of metal and including aluminum oxide,
a second layer that is a sintered body stacked on the first layer, mainly composed of metal, and not including aluminum oxide, and
a third layer that is a sintered body stacked on the second layer, mainly composed of metal, and including aluminum oxide.

8. A substrate fixing device, comprising:
a base plate; and
the electrostatic chuck according to claim 7 mounted on one surface of the base plate.
